(19) United States
(12) Patent Application Publication
(10) Pub. No.: US 2015/0132929 A1
(43) Pub. Date: May 14, 2015

(54) METHOD FOR INJECTING DOPANT INTO SUBSTRATE TO BE PROCESSED, AND PLASMA DOPING APPARATUS

(71) Applicant: TOKYO ELECTRON LIMITED, Tokyo (JP)

(72) Inventors: Masahiro Horigome, Hokuto (JP); Hirokazu Ueda, Yamanashi (JP); Masahiro Oka, Yamanashi (JP); Masahiro Yamazaki, Miyagi (JP); Takenao Nemoto, Miyagi (JP)

(73) Assignee: TOKYO ELECTRON LIMITED, Tokyo (JP)

(21) Appl. No.: 14/397,953

(22) PCT Filed: Apr. 5, 2013
(86) PCT No.: PCT/JP2013/060509

§ 371 Date: Oct. 30, 2014

(30) Foreign Application Priority Data
May 1, 2012 (JP) 2012-104632

(51) Int. Cl. H01L 21/223; H01L 21/22; H01J 37/32

(52) U.S. Cl. CPC H01L 21/2236; H01J 37/32192; H01J 37/32412; H01J 37/32449; H01L 21/2225; H01J 2237/3365; H01J 2237/31705
USPC 438/513; 118/704

(57) ABSTRACT

Provided is a method for injecting a dopant into a substrate to be processed. A method in one embodiment of the present invention includes: (a) a step for preparing, in a processing container, a substrate to be processed; and (b) a step for injecting a dopant into the substrate by supplying a doping gas containing AsH₃, an inert gas, and H₂ gas to the inside of the processing container, and applying plasma excitation energy to the inside of the processing container. In the step of injecting the dopant, the ratio of hydrogen partial pressure to the gas total pressure in the processing container is set within the range of 0.0015-0.003.

### TECHNICAL FIELD

Exemplary embodiments of the present disclosure relate to a method of injecting a dopant into a substrate to be processed (“processing target substrate”), and a plasma doping apparatus which may be used for performing the method.

### BACKGROUND

In manufacturing a semiconductor device, a doping process is performed on some regions of a processing target substrate to inject a dopant. As such a semiconductor, for example, a MOS transistor is known. When manufacturing the MOS transistor, the doping process is performed so as to form an extension region such as a lightly doped drain (LDD), a source region, and a drain region. As a method of performing the doping process, an ion beam injection method is known.

Meanwhile, development of semiconductors with a three-dimensional structure such as, for example, a fin-type MOS transistor has been recently progressed. However, the ion beam injection method is not able to uniformly irradiate ions on a three-dimensional surface, i.e. a plurality of differently oriented surfaces. For this reason, a plasma doping method, which is capable of relatively uniformly injecting a dopant into the three-dimensional surface, has attracted attention.

The plasma doping method is a technology of injecting a dopant into a processing target substrate by generating plasma of a doping gas within a processing container. An example of the plasma doping is disclosed in Patent Document 1.

### PRIOR ART DOCUMENT

### Patent Document

Patent Document 1: Japanese Patent Laid-Open No. H6-252083

### SUMMARY OF THE INVENTION

### Problem to be Solved

In the plasma doping method, an oxide of the dopant may be produced within the processing container and become a source of particles. The particles are attached to a processing target substrate and generate a defect, thereby causing a failure of a semiconductor device.

Accordingly, what is requested is a plasma doping method and a plasma doping apparatus which are capable of reducing the number of particles.

### Means to Solve the Problem

An aspect of the present disclosure is a method of injecting a dopant into a processing target substrate. The method includes: (a) a step of preparing a processing target substrate within a processing container, and (b) a step of injecting a dopant into the processing target substrate by supplying a doping gas containing AsH₃, an inert gas, and H₂ gas into the processing container as well as applying plasma excitation energy to the inside of the processing container. In the step of injecting the dopant, a ratio of hydrogen partial pressure to total gas pressure within the processing container ranges from 0.0015 to 0.003. In an exemplary embodiment, the plasma excitation energy may be microwaves.

In the plasma doping using a doping gas containing AsH₃, i.e. arsine, arsenic and oxygen may react together with each other within the processing container to generate arsenic oxide, i.e. As₂O₃. The arsenic oxide may be a source of particles. However, in the present method, since the above-mentioned amount of hydrogen exists, the amount of arsenic oxide reduced by hydrogen increases and as a result, the number of particles is greatly reduced.

In an exemplary embodiment, in the step of injecting the dopant, the inert gas may be supplied into the processing container as well as the plasma excitation energy may be applied to the inside of the processing container to generate plasma of the inert gas, and then, the doping gas, the inert gas, and the H₂ gas may be supplied into the processing container as well as the plasma excitation energy may be applied to the inside of the processing container. According to the present exemplary embodiment, since the doping gas may be supplied into the processing container after the plasma is ignited by supplying the inert gas, the arsine is suppressed from being polymerized to form a particle source when the plasma is ignited.

A method of an exemplary embodiment may further include, prior to preparing the processing target substrate within the processing container, preparing a wafer, i.e. a dummy wafer, within the processing container, supplying the inert gas into the processing container, and applying the plasma excitation energy to the inside of the processing container. According to the present exemplary embodiment, as a pre-processing for the step of injecting the dopant into the processing target substrate, the dummy wafer may be accommodated in the processing container so as to clean the inside of the processing container. In the pre-processing, the arsine remaining in the processing container may be activated by the plasma, and the hydrogen generated thereby may reduce the arsenic oxide. As a result, the number of particles may be reduced.

In an exemplary embodiment, the inert gas may be helium (He) gas. The He gas has a small mass as compared to another inert gas such as Ar gas. Therefore, when the He gas is used as the inert gas, a structural deformation of a semiconductor device may be suppressed.

In addition, another aspect of the present disclosure relates to a plasma doping apparatus. The plasma doping apparatus is provided with a processing container, a mounting table, first to third supply sections, an energy supply unit, and a control unit. The mounting table is provided within the processing container. The first supply section supplies a doping gas containing AsH₃ into the processing container. The second supply section supplies an inert gas into the processing container. The third supply section supplies H₂ gas into the processing container. The energy supply unit applies plasma excitation energy to the inside of the processing container. The control unit controls the first supply section, the second supply section, and the third supply section. The control unit controls the first supply section, the second supply section, and the third supply section such that a ratio of hydrogen partial pressure to total gas pressure within the processing container ranges 0.0015 to 0.003. According to the present apparatus, since the hydrogen within the processing container is set to the above-mentioned amount by the control unit, the amount of arsenic oxide reduced by the hydrogen increases and the number of particles is greatly reduced. In addition, in an exemplary embodiment, the energy supply unit may supply microwaves as the plasma excitation energy.

In an exemplary embodiment, the control unit may control the first supply section, the second supply section, the third supply section, and the energy supply unit to supply the inert gas into the processing container as well as to apply the plasma excitation energy to the inside of the processing container to generate plasma of the inert gas, and then, to supply the doping gas, the inert gas, and the H₂ gas into the processing container as well as to apply the plasma excitation energy to the inside of the processing container. According to the apparatus of the present exemplary embodiment, since the doping gas may be supplied into the processing container after the plasma is ignited by supplying the inert gas, the arsine is suppressed from being polymerized to form a particle source when the plasma is ignited.

In an exemplary embodiment, the control unit may control the second supply section and the energy supply unit to supply the inert gas into the processing container and to apply the plasma excitation energy to the inside of the processing container. The control by the control unit may be performed as a pre-processing prior to injecting the dopant into the processing target substrate. By the pre-processing, the arsine remaining in the processing container may be activated by the plasma, and the hydrogen generated thereby may reduce the arsenic oxide. As a result, the number of particles may be reduced.

In an exemplary embodiment, the second supply section may supply He gas as the inert gas. When the He gas is used as the inert gas, a structural deformation of a semiconductor device may be suppressed.

### Effect of the Invention

As described above, according to aspects and exemplary embodiments of the present disclosure, a plasma doping method and a plasma doping apparatus which are capable of reducing the number of particles are provided.

### BRIEF DESCRIPTION OF THE DRAWINGS

FIG. 1 is a cross-sectional view schematically illustrating a plasma doping apparatus according to an exemplary embodiment.

FIG. 2 is a plan view illustrating a slot plate of an exemplary embodiment.

FIG. 3 is a flow chart illustrating an exemplary embodiment of a method of injecting a dopant into a processing target substrate.

FIG. 4 is a graph representing an evaluation result in Test Example 1.

FIG. 5 is a graph representing evaluation results of Text Example 2 and a comparative test example.

### DETAILED DESCRIPTION TO EXECUTE THE INVENTION

Hereinafter, various exemplary embodiments will be described in detail with reference to the accompanying drawings. In addition, the same or corresponding parts in respective drawings will be denoted by the same symbols.

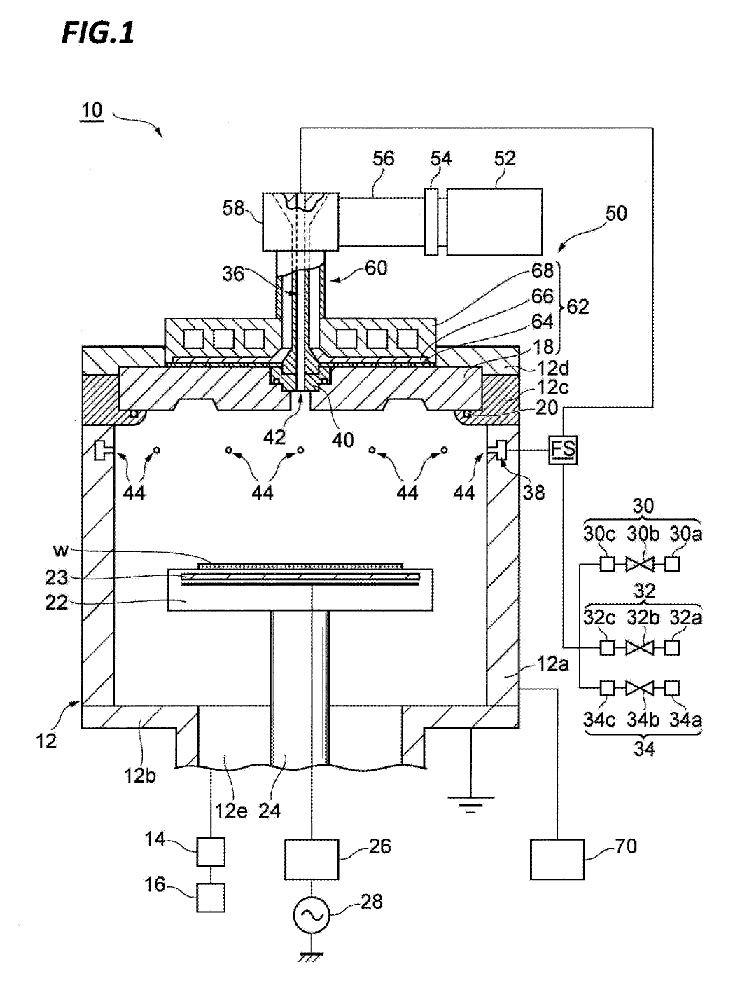

First, a plasma doping apparatus according to an exemplary embodiment will be described. FIG. 1 is a view illustrating a plasma doping apparatus according to an exemplary embodiment. The plasma doping apparatus 10 is provided with a processing container 12. The processing container 12 defines a space configured to accommodate and process a processing target substrate W therein.

In an exemplary embodiment, the processing container 12 includes a side wall 12a, a bottom portion 12b, a top portion 12c, and a lid 12d. The side wall 12a has a substantially cylindrical shape. The bottom portion 12b is connected to a lower end of the side wall 12a. An exhaust port 12e is formed in the bottom portion 12b, and an exhaust apparatus 16 such as a vacuum pump is connected to the exhaust port 12e through a pressure regulator 14. The pressure regulator 14 controls an exhaust amount based on a measured pressure value within the processing container 12.

The top portion 12c is connected to an upper end of the side wall 12a, and a dielectric window 18 is provided to close an opening formed in the top portion 12c. The dielectric window 18 is a substantially disc-shaped member made of quartz and is sandwiched between the top portion 12c and the lid 12d, and a sealing member 20 such as an O-ring may be provided between the dielectric window 18 and the top portion 12c. As a result, the inside of the processing container 12 is hermetically sealed.

Within the processing container 12, a mounting table 22 is provided to face the dielectric window 18. The mounting table 22 may be supported by an insulative tubular support unit 24 which extends upwardly from the bottom portion 12b side. The mounting table 22 includes an electrostatic chuck on a top surface thereof, and may electrostatically attract a processing target substrate W by the electrostatic chuck. Within the mounting table 22, a temperature adjustment mechanism 23 is provided so as to adjust the temperature of the processing target substrate W.

In addition, the mounting table 22 also serves as a high frequency bias electrode. A high frequency power supply 28 is connected to the mounting table 22 through a matching unit 26. The high frequency power supply 28 applies a high frequency bias voltage of a predetermined power of, for example, 13.56 MHz to the mounting table 22 through the matching unit 26. The matching unit 26 accommodates a matcher configured to match the high frequency power supply 28 side impedance and load side impedance, mainly such as an electrode, plasma, and the processing container 12, and a blocking condenser for self-bias generation is included in the matcher. In addition, the high frequency bias voltage may be supplied as needed during plasma doping.

The plasma doping apparatus 10 further includes gas supply sources 30, 32, and 34. The gas supply source 30 includes a gas source 30a, a valve 30b, and a flow rate controller 30c such as a mass flow controller. The gas source 30a is a gas source of the doping gas. The gas supply source 30 supplies the doping gas after controlling the flow rate of the doping gas. The doping gas contains arsine (AsH₃). Specifically, the doping gas is a gas in which arsine is diluted by an inert gas. The dilution gas is He gas. In an exemplary embodiment, a ratio of arsine partial pressure to total doping gas pressure is, for example, 0.7%. In addition, the dilution gas may be another inert gas such as, for example, Ar gas.

The gas supply source 32 includes a gas source 32a, a valve 32b, and a flow rate controller 32c such as a mass flow controller. The gas source 32a is a gas source of an inert gas. The gas supply source 32 supplies the inert gas after controlling the flow rate of the inert gas. In an exemplary embodiment, the inert gas is He gas. In addition, the dilution gas may be another inert gas such as Ar gas.

In addition, the gas supply source 34 includes a gas source 34a, a valve 34b, and a flow rate controller 34c such as a mass flow controller. The gas source 34a is a gas source of hydrogen (H₂) gas. The gas supply source 34 supplies the hydrogen gas after controlling the flow rate of the hydrogen gas.

The gas supply sources 30, 32, and 34 are connected to a flow splitter FS. The flow splitter FS splits the supplied gas into a gas flow path 36 and a gas flow path 38. The gas flow path 36 is provided inside a coaxial waveguide to be described later. In an exemplary embodiment, the gas flow path 36 is defined by a pipe provided inside the coaxial waveguide and an injector 40 provided in a central opening of the dielectric window 18. The injector 40 additionally provides a gas injection hole 42 which is continuous with the gas flow path. The gas injection hole 42 injects gas downward toward the mounting table 22 from a position above the mounting table 22. In the following description, the gas injection hole 42 and the gas flow path 36 may be referred to as a “central inlet”.

The gas flow path 38 extends annularly within the side wall 12a. The gas flow path 38 is positioned between the mounting table and the dielectric window 18 in the height direction. A plurality of gas injection holes 44 is connected to the gas flow path 38. The gas injection holes 44 are arranged annularly, and inject a gas toward the central axis from the outside in relation to the central axis of the processing container 12. In addition, in the following description, the gas injection holes 44 and the gas flow path 38 may be referred to as a “peripheral inlet”.

The gas flow path 36, the gas injection hole 42, the gas flow path 38, and the gas injection holes 44 form a first supply section of an exemplary embodiment together with the gas supply source 30, also form a second supply section of an exemplary embodiment together with the gas supply source 32, and further forms a third supply section together with the gas supply source 34.

In addition, the plasma doping apparatus 10 further includes an energy supply unit 50 which supplies plasma excitation energy to the inside of the processing container. In an exemplary embodiment, the energy supply unit 50 is configured to supply microwaves as plasma excitation energy from a radial line slot antenna into the processing container 12, and includes a microwave generator 52, a tuner 54, a waveguide 56, a mode converter 58, a coaxial waveguide 60, and an antenna 62.

The microwave generator 52 generates TE mode microwaves of, for example, 2.45 GHz. The microwave generator 52 is connected to a mode converter 58 through the tuner 54 and the waveguide 56. The mode converter 58 converts the mode of microwaves generated by the microwave generator 52 and propagated through the tuner 54 and the waveguide 56 into a TEM mode. An upper end of the coaxial waveguide 60 is connected to the mode converter 58. A lower end of the coaxial waveguide 60 is connected to the antenna 62.

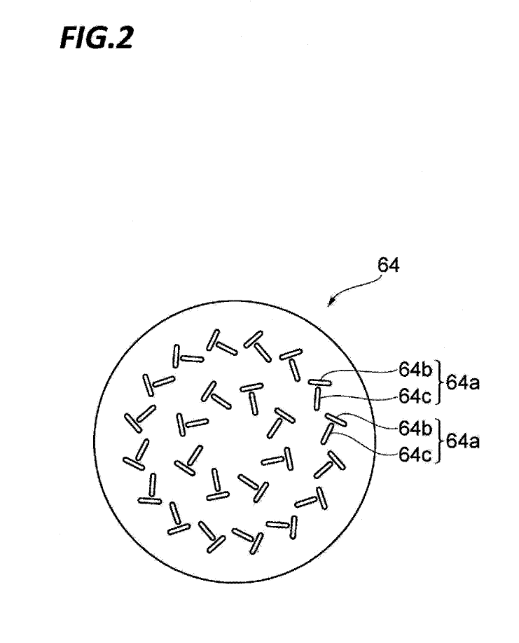

The antenna 62 is provided within the central opening of the lid 12d of the processing container 12. The antenna 62 includes a dielectric window 18, a slot plate 64, a dielectric plate 66, and a cooling jacket 68. The slot plate 64 is provided just above the dielectric window 18. A lower end of an inner conductor of the coaxial waveguide 60 is connected to the slot plate 64. FIG. 2 is a plan view illustrating a slot plate of an exemplary embodiment. As illustrated in FIG. 2, the slot plate 64 is a substantially disc-shaped member made of a metal. The slot plate 64 is provided with a plurality of slot pairs 64a. Each of the plurality of slot pairs 64a includes slot holes 64b and 64c which extend in crossing or orthogonal directions. The plurality of slot pairs 64a is arranged in a radial direction and a circumferential direction in the slot plate 64.

The dielectric plate 66 is a substantially disc-shaped member made of quartz, and is sandwiched between the cooling jacket 68 and the slot plate 64. The cooling jacket 68 is provided so as to cool, for example, the dielectric plate 66, and a coolant flow path is provided therein. A lower end of an outer conductor of the coaxial waveguide 60 is connected to the top of the cooling jacket 68.

In the plasma doping apparatus 10, the microwaves propagated from the coaxial waveguide 60 are propagated from the slots of the slot plate 64 to the dielectric window 18 while being reflected between the slot plate 64 and the cooling jacket 68. The microwaves passing through the dielectric window 18 generates an electric field just below the dielectric window 18 to generate plasma within the processing container 12. Like this, the plasma doping apparatus 10 may excite plasma by microwaves without using a magnetic field.

When the plasma doping apparatus 10 generates microwave plasma, a so-called plasma generation region, in which an electron temperature of plasma is relatively high as compared to other regions, is formed in a region just below the dielectric window 18. In addition, below the plasma generation region, a plasma diffusion region is formed in which the plasma generated in the plasma region is diffused. The plasma diffusion region is a region in which the electron temperature is relatively low, and plasma doping to a processing target substrate W is performed in the plasma diffusion region. Accordingly, the plasma doping apparatus 10 may suppress damage to the processing target substrate W during the plasma doping. In addition, the plasma doping apparatus 10 may perform efficient plasma doping since it may generate high density plasma.

The plasma doping apparatus 10 further include a control unit 70. The control unit 70 includes a programmable central processing unit (CPU), and controls respective units of the plasma doping apparatus 10 by transmitting a control signal to the respective units. Specifically, the control unit 70 controls the pressure regulator 14, the exhaust apparatus 16, the temperature adjustment mechanism 23, the high frequency power supply 28, the matching unit 26, the microwave generator 52, and the gas supply sources 30, 32, and 34.

Hereinafter, a plasma doping method performed in the plasma doping apparatus 10 under the control of the control unit 70 will be described as an exemplary embodiment of a method of injecting a dopant into a processing target substrate.

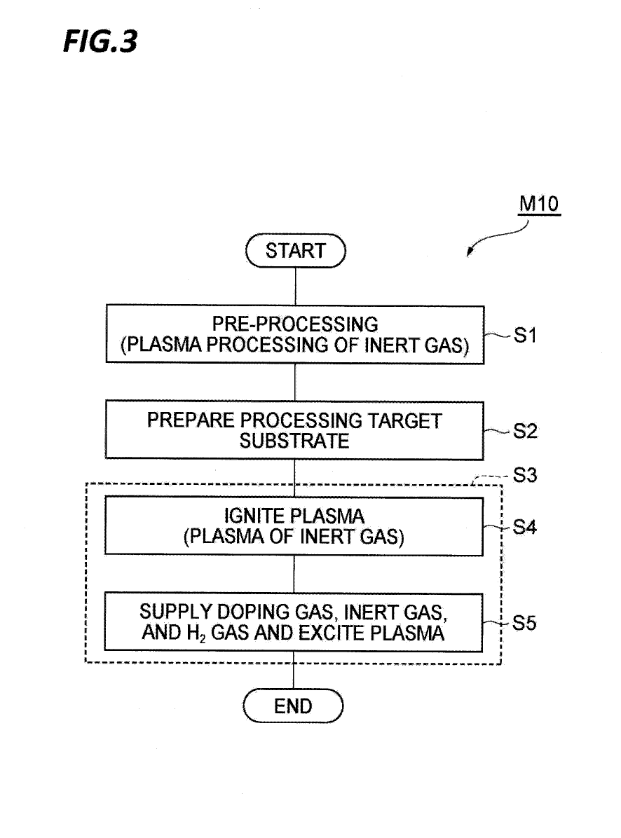

FIG. 3 is a flowchart illustrating an exemplary embodiment of a method of injecting a dopant into a processing target substrate. In an exemplary embodiment, a method M10 includes a pre-processing step S1. The pre-processing step S1 is a processing for removing particles of arsenic oxide generated by a previously performed processing, i.e. As₂O₃. The particles may be generated by, for example, bonding of As (arsenic) of arsine contained in the doping gas and oxygen contained in a member within the plasma doping apparatus 10, for example, the dielectric window 18, or reaction between arsine remaining within the processing container 12 after plasma doping and oxygen used for plasma cleaning within the processing container 12.

In pre-processing step S1, a dummy wafer is mounted on the mounting table 22, and under the control of the control unit 70, an inert gas is supplied from the gas supply source 32, and microwaves are supplied from the energy supply unit 50. As a result, plasma of the inert gas is generated within the processing container 12. In pre-processing step S1, the arsine remaining within the processing container 12 is activated by the plasma of the inert gas. Hydrogen generated when the arsine is activated reduces arsenic oxide and generates arsine again. As a result, in pre-processing step S1, the number of particles of the arsenic oxide is reduced.

Subsequently, in method M10, a processing target substrate W is prepared within the processing container 12 in step S2. Specifically, the processing target substrate W is conveyed into the processing container 12 by a conveyance device, and the processing target substrate W is mounted on the mounting table 22.

Subsequently, in step M10, plasma doping is performed on the processing target substrate W in step S3. In an exemplary embodiment, step S3 may include step S4 and step S5. In step S4, prior to injecting the doping gas, plasma is ignited within the processing container 12 supplied with the inert gas. Specifically, in step S4, under the control of the control unit 70, the inert gas is supplied from the gas supply source 32 and microwaves are supplied from the energy supply unit 50. As a result, plasma of the inert gas is generated within the processing container 12. Step S4 is performed for, for example, 7 sec. In addition, in step S4, the plasma may be ignited at a pressure of, for example, 40 Pa which is higher than that in step S5 to be described later. In step S4, since the plasma of the inert gas is generated without supplying the doping gas, polymerization of the arsine under the high pressure is suppressed and as a result, occurrence of particles may be suppressed.

Subsequently, in method M10, injection of a dopant into the processing target substrate W is performed in step S5. Specifically, in step S5, under the control of the control unit 70, a doping gas is supplied from the gas supply source 30, an inert gas is supplied from the gas supply source 32, hydrogen (H₂) gas is supplied from the gas supply source 34, and microwaves are supplied from the energy supply unit 50. In step S5, the arsine is dissociated so that active species such as arsenic ions or arsenic radicals are generated, and when the active species react with the processing target, plasma doping of the substrate W is performed.

In addition, in step S5, by the control of the gas supply source 30, 32, and 34 by the control unit 70, a ratio of hydrogen partial pressure to total pressure of a gas supplied into the processing container 12, that is, (hydrogen partial pressure)/(total pressure) is set to be in a range of 0.0015 to 0.003. When (hydrogen partial pressure)/(total pressure) is set to a value in this range, the number of particles of arsenic oxide is reduced. Here, during the plasma doping, a member within the processing container 12, for example, the dielectric window 18 made of quartz reacts with the arsenic to generate As₂O₃. However, since hydrogen exists within the processing container 12 such that (hydrogen partial pressure)/(total pressure) is 0.0015 or more, the hydrogen efficiently reduces As₂O₃, thereby generating arsine again. In addition, when (hydrogen partial pressure)/(total pressure) is 0.003 or less, the amount of hydrogen is excessive, and the hydrogen may suppress the silicon in the processing target substrate W from being etched. The etched locations are defects and may also be counted as particles. As a result, according to step S5, the number of occurring particles may be reduced.

The inert gas used in steps S4 and S5 of the above-described method M10 may be He gas. When the He gas has a mass which is smaller than that of Ar gas and is used as the inert gas, a structural deformation of a semiconductor formed on the processing target substrate W may be suppressed.

Hereinafter, test examples using the plasma doping apparatus 10 will be described.

### Test Example 1

In Test Example 1, eleven (11) processing target substrates made of silicon were processed using (hydrogen partial pressure)/(total pressure) as a variable parameter to obtain Samples 1 to 11. Flow rates of H₂ gas, flow rates of doping gas, flow rates of inert gas (He gas), and (hydrogen partial pressure)/(total pressure) when Samples 1 to 11 were obtained are represented in Table 1. In addition, as the doping gas, a gas containing arsine and He, in which a ratio of arsine partial pressure to total pressure of the doping gas is 0.7% and a ratio of He partial pressure to the total pressure is 99.3%, was used.

TABLE 1

| | H₂ Gas | Doping Gas | Inert Gas | (Hydrogen Partial |
|---|---|---|---|---|
| | Flow Rate | Flow Rate | Flow Rate | Pressure)/(Total |
| | (sccm) | (sccm) | (sccm) | Pressure) |
| Sample 1 | 0 | 98 | 902 | 0.001 |
| Sample 2 | 1 | 98 | 901 | 0.002 |
| Sample 3 | 0 | 98 | 902 | 0.001 |
| Sample 4 | 0 | 140 | 860 | 0.001 |
| Sample 5 | 0 | 196 | 804 | 0.002 |
| Sample 6 | 0 | 291 | 709 | 0.003 |
| Sample 7 | 1 | 98 | 901 | 0.002 |
| Sample 8 | 1 | 140 | 859 | 0.002 |
| Sample 9 | 1 | 196 | 803 | 0.003 |
| Sample 10 | 0 | 105 | 895 | 0.001 |
| Sample 11 | 1 | 105 | 894 | 0.002 |

In addition, other conditions when Samples 1 to 11 were obtained were as follows.

Diameter of processing target substrate: 300 mm

Temperature of processing target substrate: 60° C.

Ratio of gas flow rate at central inlet and gas flow rate at peripheral inlet: 20:80

Microwave power: 3.0 kW

High frequency bias power: 450 W

Pressure within processing container: 20 Pa

Processing time: 40 sec

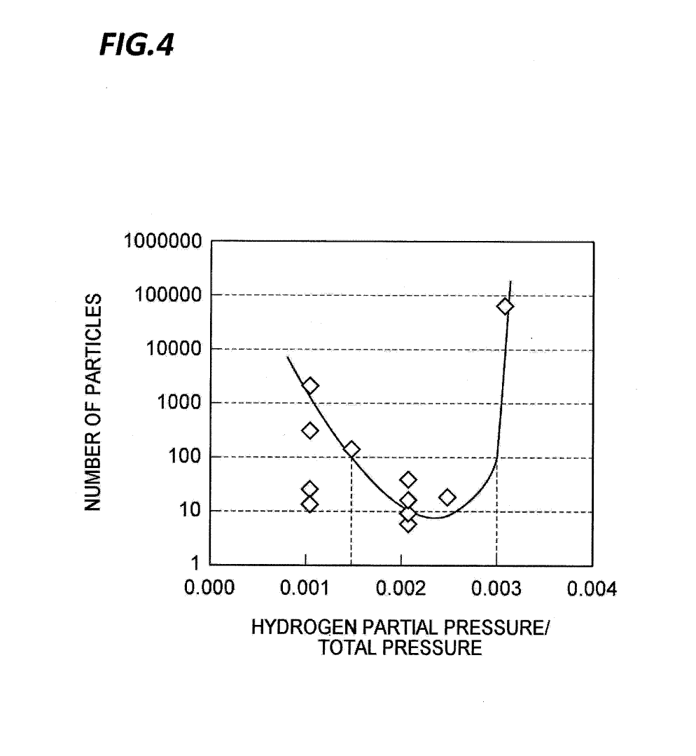

In Test Example 1, the number of particles attached to the surfaces of processing target substrates of Sample 1 to 11 and have a size of 0.0042 μm or more was counted using “Surfscan SP2XP” which is a surface inspection apparatus manufactured by KLA-Tencor Corporation. The results are represented in FIG. 4. In the graph illustrated in FIG. 4, the horizontal axis represents (hydrogen partial pressure)/(total pressure) when Samples 1 to 11 were obtained, and the vertical axis represents the counted number of particles. As illustrated in FIG. 4, in Test Example 1, it was confirmed that the number of particles may be maintained 100 or less by setting (hydrogen partial pressure)/(total pressure) to be in the range of 0.0015 to 0.003.

### Test 2

In Test Example 2, effects of steps S1 and S4 were confirmed by performing plasma doping on the processing target substrates which have a diameter of 300 mm and are made of silicon using a doping gas after steps S1 and S4 were performed. Respective conditions of Test 2 were as follows.

(Step S1)

Temperature of dummy wafer: 60° C.

Flow rate of inert gas (He gas): 1000 sccm

Ratio of gas flow rate at central inlet and gas flow rate at peripheral inlet: 20:80

Microwave power: 3.0 kW

High frequency bias power: 450 W

Pressure within processing container: 20 Pa

Processing time: 100 sec

(Step S4)

Temperature of processing target substrate: 60° C.

Flow rate of inert gas (He gas): 1000 sccm

Ratio of gas flow rate at central inlet and gas flow rate at peripheral inlet: 20:80

Microwave power: 3.0 kW

High frequency bias power: 450 W

Pressure within processing container: 40 Pa

Processing time: 7 sec

(Plasma Doping after Step S4)

Temperature of processing target substrate: 60° C.

Flow rate of inert gas (He gas): 902 sccm

Flow rate of doping gas: 98 sccm

Ratio of arsine partial pressure to total doping gas pressure: 0.7%

Ratio of He gas partial pressure to total doping gas pressure: 99.3%

Ratio of gas flow rate at central inlet and gas flow rate at peripheral inlet: 20:80

Microwave power: 3.0 kW

High frequency bias power: 450 W

Pressure within processing container: 40 Pa

Processing time: 40 sec

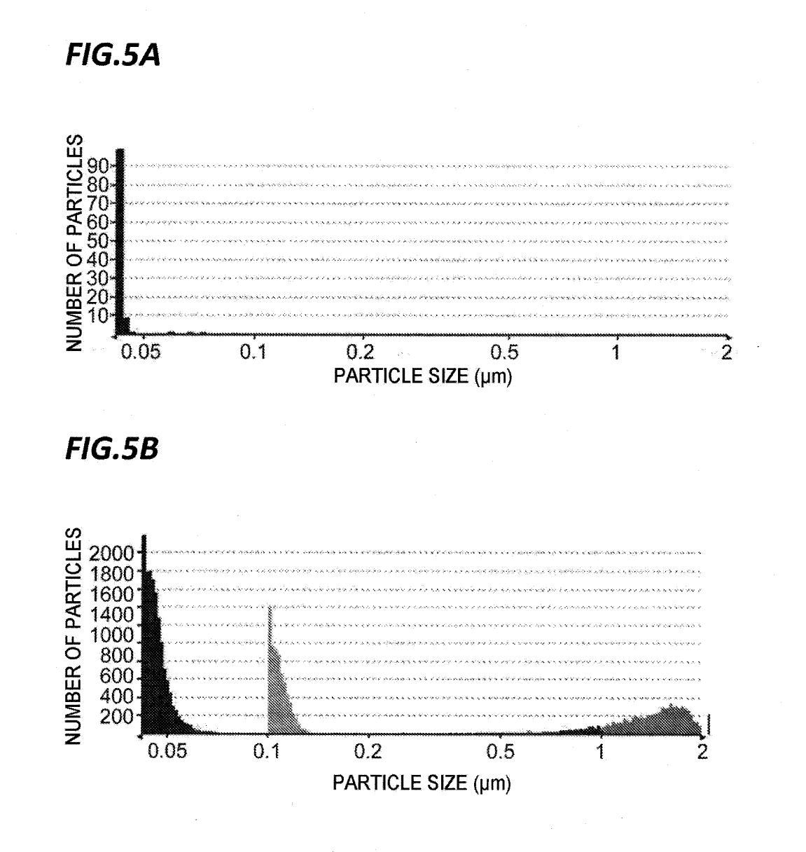

In a comparative test example, plasma doping (step S4) having conditions which are the same as those of Test Example 2 was performed without performing steps S1 and S4. In addition, the number of particles which were attached to processing target substrates and have 0.042 μm or more was counted on each of the processing target substrates obtained in Test Example 2 and the comparative test example, using “Surfscan SP2XP” which is a wafer surface inspection apparatus manufactured by KLA-Tencor Corporation. The results are represented in FIGS. 5A and 5B. FIGS. 5A and 5B are graphs in which the horizontal axes represent particle size and the vertical axes represent the number of particles. FIGS. 5A and 5B represent the number of particles attached to the processing target substrates obtained in Example 2 and the comparative example, respectively. As will be obvious from comparison of FIGS. 5A and 5B, it was confirmed that the number of particles is greatly reduced by performing steps S1 and S4. In addition, the number of particles attached to the processing target substrates obtained in Test Example 2 was 100 or less while the number of particles attached to the processing target substrates obtained in the comparative examples was 10000 or more.

From the above results, it was confirmed that the number of particles may be further reduced when (hydrogen partial pressure)/(total pressure) is set to be in the range of 0.0015 to 0.003 during plasma doping using a doping gas containing arsine, and steps S1 and S4 were performed before injecting a dopant into a processing target substrate.

### DESCRIPTION OF SYMBOLS

10: plasma doping apparatus, 12: processing container, 14: pressure regulator, 16: exhaust apparatus, 18: dielectric window, 22: mounting table, 23: temperature adjustment mechanism, 28: high frequency power supply, 30: gas supply source (doping gas), 32: gas supply source (inert gas), 34: gas supply source (hydrogen gas), 50: energy supply unit, 60: coaxial waveguide, 62: antenna, 64: slot plate, 66: dielectric plate, 68: cooling jacket, 70: control unit, W: processing target substrate

1. A method of injecting a dopant into a processing target substrate, the method comprising:
preparing a processing target substrate within a processing container; and
injecting the dopant into the processing target substrate by supplying a doping gas containing AsH₃, an inert gas, and H₂ gas into the processing container as well as applying plasma excitation energy to the inside of the processing container,
wherein, when injecting the dopant, a ratio of hydrogen partial pressure to total gas pressure within the processing container ranges from 0.0015 to 0.003.

2. The method of claim 1, wherein, when injecting the dopant, the inert gas is supplied into the processing container as well as the plasma excitation energy is applied to the inside of the processing container to generate plasma of the inert gas, and then, the doping gas, the inert gas, and the H₂ gas are supplied into the processing container as well as the plasma excitation energy is applied to the inside of the processing container.

3. The method of claim 1, further comprising, prior to preparing the processing target substrate within the processing container, preparing a wafer within the processing container, supplying the inert gas into the processing container, and applying the plasma excitation energy to the inside of the processing container.

4. The method of claim 1, wherein the inert gas is He gas.

5. The method of claim 1, wherein the plasma excitation energy is microwaves.

6. A plasma doping apparatus comprising:
a processing container;
a mounting table provided within the processing container;
a first supply section configured to supply a doping gas containing AsH₃ into the processing container;
a second supply section configured to supply an inert gas into the processing container;
a third supply section configured to supply H₂ gas into the processing container;
an energy supply unit configured to apply plasma excitation energy to the inside of the processing container; and
a control unit configured to control the first supply section, the second supply section, and the third supply section,
wherein the control unit controls the first supply section, the second supply section, and the third supply section such that a ratio of hydrogen partial pressure to total pressure gas within the processing container ranges from 0.0015 to 0.003.

7. The plasma doping apparatus of claim 6, wherein the control unit controls the first supply section, the second supply section, the third supply section, and the energy supply unit to supply the inert gas into the processing container as well as to apply the plasma excitation energy to the inside of the processing container to generate plasma of the inert gas, and then, to supply the doping gas, the inert gas, and the H₂ gas into the processing container as well as to apply the plasma excitation energy to the inside of the processing container.

8. The plasma doping apparatus of claim 6, wherein the control unit controls the second supply section and the energy supply unit to supply the inert gas into the processing container as well as to apply the plasma excitation energy to the inside of the processing container.

9. The plasma doping apparatus of claim 6, wherein the second supply section supplies He gas as the inert gas.

10. The plasma doping apparatus of claim 6, wherein the energy supply unit supplies microwaves as the plasma excitation energy.
